(19) United States
(12) Patent Application Publication
(10) Pub. No.: US 2025/0194437 A1
(43) Pub. Date: Jun. 12, 2025

(54) TOPOLOGICAL SUPERCONDUCTING DEVICE

(71) Applicant: YEDA RESEARCH AND DEVELOPMENT CO. LTD., Rehovot (IL)

(72) Inventors: Yuval OREG, Rehovot (IL); Adiel STERN, Rehovot (IL); Omri LESSER, Rehovot (IL)

(73) Assignee: YEDA RESEARCH AND DEVELOPMENT CO. LTD., Rehovot (IL)

(21) Appl. No.: 18/845,443

(22) PCT Filed: Apr. 4, 2023
(86) PCT No.: PCT/IL2023/050358

§ 371 Date: Sep. 10, 2024

Related U.S. Application Data
(60) Provisional application No. 63/355,680, filed on Jun. 27, 2022.
(60) Provisional application No. 63/327,403, filed on Apr. 5, 2022.

(51) Int. Cl. H10N 60/12; G06N 10/40; H10N 60/10

(52) U.S. Cl. CPC H10N 60/12; G06N 10/40; H10N 60/128

(57) ABSTRACT

Provided is a topological superconductivity device based on phase control. The invention relies on two key ingredients: at least three superconducting forming at least two SNS junctions with phase winding, and unequal Fermi velocities for the two spin branches transverse to the junction. The two phase differences between the three superconductors define a two-dimensional parameter plane which includes large topological regions. Arrays of topological devices are disclosed which comprise a plurality of individual topological devices. Material platforms are provided which exhibit unequal Fermi velocities.

### TECHNOLOGICAL FIELD

The presently disclosed subject matter relates to the field of topological superconducting devices which utilize unequal Fermi velocities and phase winding.

### BACKGROUND

Current proposals for topological qubits are based on combining two superconducting pads, a semiconductor with strong spin-orbit coupling that connects to the superconductor(s), and a magnetic field of the order of one Tesla. Progress in the realization of these proposals is hampered by the suppressing effect of the magnetic field on superconductivity, and by material limitations, in particular associated with the need to interface the superconductors and the semiconductor.

In the present invention the requirements imposed on the materials involved are significantly reduced, expressing them as easy-to-fulfill requirements on the electronic band-structure.

A goal/aim of the present invention is to provide a general prescription for inducing topological superconductivity. A key condition is that the material/s have unequal Fermi velocities for two spin branches of a device, with phase winding of the superconductors.

A further goal/aim of the invention is to provide a platform which is composed of a single material with no need for interfacing, thus paving a novel way to overcome the obstacles in the way of realizing a topological qubit.

### SUMMARY

In one embodiment this invention provides a topological superconducting device comprising: three adjacent superconducting regions, comprising at least one material, disposed on a substrate, giving rise to two spin branches, wherein the three adjacent superconducting regions exhibit phase winding; and wherein one spin branch has a Fermi velocity that is not the same as the Fermi velocity of the second spin branch.

In one embodiment the topological superconducting device comprises at least one gate. In one embodiment a plurality of gates is used on superconducting regions(S) and/or non-superconducting regions (N). In one embodiment the gate can induce superconductivity. In one embodiment the topological superconducting device further comprises two non-superconducting regions disposed between three adjacent superconducting regions, arranged as two SNS junctions with one overlapping superconducting region forming an SNSNS junction.

In one embodiment, the three adjacent superconducting regions are arranged in parallel to one another and/or in a planar configuration. In one embodiment the substrate of the topological superconducting device is selected from a group comprising: a non-superconducting metal, a 2D electron gas material, a semiconductor, a dielectric medium, silicon, an oxide or combination thereof. In one embodiment two

SNS junctions comprise at least one material wherein at least one gate is configured to modulate superconductivity in at least one material. In one embodiment of the topological superconducting device at least one gate is configured to modulate phase differences between three adjacent superconducting regions. In one embodiment three adjacent superconducting regions are gate-defined wires. In one embodiment the middle superconducting region of said three adjacent superconducting regions is wider than the width of the outer superconducting regions. In one embodiment at least one material is selected from a group comprising: a transition metal dichalcogenide (TMD), Al, Nb, Pb, NbSe₂, HgTe, InAs and InSb. In one embodiment of the topological superconducting device the TMD is selected from a group comprising: TaS₂, MoS₂, MoSe₂, MoTe₂, WS₂, WSe₂, WTe₂ or combination thereof. In one embodiment any of the materials can be doped.

In one embodiment the phase winding is 2π or occur at multiples of 2π. In one embodiment the topological superconducting further comprises a periodic modulation on top of, underneath and/or inside at least one of said three adjacent superconducting regions. In one embodiment the topological superconducting device further comprises at least one additional superconducting region parallel to said three adjacent superconducting regions. In one embodiment the topological superconducting device further comprises at least one additional non-superconducting region between at least one additional superconducting region parallel to three adjacent superconducting regions. In one embodiment the topological superconducting device further comprises additional layers in-between, next to, on top of and/or underneath said least three superconducting regions. In one embodiment at least one gate comprises a top-gate, back-gate, side-gate or combination thereof.

In one embodiment this invention provides a quantum computer comprising the topological device disclosed herein. In one embodiment the invention provides a topological superconducting array device comprising a plurality of the topological device disclosed herein. In one embodiment this invention provides a quantum computer comprising the topological array device.

### BRIEF DESCRIPTION OF THE DRAWINGS

In order to better understand the subject matter that is disclosed herein and to exemplify how it may be carried out in practice, embodiments will be described, by way of non-limiting examples only, with reference to the accompanying drawings, in which:

FIG. 1 is a schematic illustration of various embodiments of the relative widths of superconducting versus non-superconducting materials in an SNSNS junction.

FIG. 2A is a schematic illustration of an SNSNS device setup with multiple gates.

FIG. 2B is a schematic illustration of an SNS device setup that can be added on to existing SNSNS devices.

FIG. 2C is a schematic illustration of an SNSNS device setup with a top layer containing a plurality of gates.

FIG. 3A is a schematic illustration of a device depicting three superconducting regions, on a 2D electron gas with a periodic modulation on the middle superconducting region.

FIG. 3B is a schematic illustration of a device depicting three separated superconducting regions, on a 2D electron gas with a periodic modulation on the middle superconducting region.

FIG. 3C is a schematic illustration of a periodic modulation in an upper material.

FIG. 3D is a schematic illustration of a periodic modulation at the interface between an upper and lower material.

FIG. 4A is a schematic illustration of a phase-biased SNSNS junction.

FIG. 4B is a graphical representation of a transverse spectrum of the SNSNS junction of FIG. 4A, using a model including next-nearest neighbor hopping.

FIG. 5 is a phase diagram for the SNSNS geometry of FIG. 4A.

FIG. 6A is a phase diagram for the SNSNS geometry of FIG. 4A, with extended regions of the phases θ, ϕ.

FIG. 6B is the phase diagram as a function of the parameters ϕ₁=ϕ+θ, ϕ₂=ϕ−θ.

For simplicity and clarity of illustration, elements shown in the figures are not necessarily drawn to scale, and the dimensions of some elements may be exaggerated relative to other elements. In addition, reference numerals may be repeated among the figures to indicate corresponding or analogous elements.

### DETAILED DESCRIPTION

In some embodiments the presently disclosed subject matter relates to inducing topological superconductivity in magnetic-field-free planar devices. In some embodiments two conditions are needed for this in a purely phase-controlled setup: superconducting phase winding and unequal Fermi velocities. In some embodiments phase winding is the time-reversal symmetry breaking mechanism. While it is true that any phase bias breaks time-reversal symmetry, the presently disclosed subject matter supports the separation of spin species that mimics the effect of the Zeeman field, when the phase winds. If the phase does not wind, the current flows back and forth between adjacent superconductors. The qualitative change that takes place when phase winding is introduced is the circulating current that flows around the system.

The role of unequal Fermi velocities is strongly linked to spin-orbit coupling. We note that a Fermi velocity imbalance does not occur when the electric field, responsible for the spin-orbit interaction, is purely out-of-plane. Additional factors, like in-plane electric fields which are common in transition metal dichalcogenides (TMDs) induce additional phases. In some embodiments, TMDs support unequal Fermi velocities in an SNSNS junction to induce a topological phase. In some embodiments, periodic modulations of at least one superconducting region are required to induce unequal Fermi velocities in an SNSNS junction.

As used herein, in reference to the structure of the device, “period modulation” refers to a physical and/or structural periodic modulation along, on top of, under and/or inside a region of the device e.g., on the surface of one of the superconducting (SC) regions and/or a coupling material, as detailed below.

The present invention provides a general prescription for inducing topological superconductivity in planar superconductor-normal-superconductor (SNS) Josephson junctions. In some embodiments Zeeman fields are not applied.

The invention relies on two key components:
at least three parallel superconducting leads forming two SNS junctions (i.e., an SNSNS junction) with phase winding, and
unequal Fermi velocities for the two spin branches transverse to the junction.

The term “Fermi velocity” herein denotes the velocity that corresponds to the Fermi energy of a particle.

The term “transverse” herein denotes a direction substantially perpendicular to a longitudinal axis. In particular, ‘transverse’ refers to the direction substantially perpendicular to parallel superconducting leads which form two SNS junctions.

The term “spin branches” herein refers to the spin states in the two separate SNS portions of an SNSNS device. In some embodiments, unequal Fermi velocities for the two spin branches in the direction transverse to the junction is required.

The term “superconducting” in the context of being a component of a device, herein denotes a surface, material or substrate which is in a superconducting state under suitable physical conditions, and which, when the device is in a functionally operational mode, is rendered superconducting by being put in the suitable physical conditions. In some embodiments the superconducting and/or gate-tunable material is termed the “functional” material.

The term “quantum proximity” herein denotes a close relative positioning of two structures, such that a physical property or state of one structure is capable of detectably affecting a quantum-mechanical property or state of the other structure.

In one embodiment, for two phase-differences between three superconductors, phase winding drives the system into a topological phase. The invention provides embodiments of physical platforms which exhibit unequal Fermi velocities. Two key points allow this objective to be exhibited. The first is the introduction of two phase differences by including three superconductors. With these two phase differences, phase winding drives the system into a topological phase. In one embodiment, the greater the difference between the Fermi velocities for the two branches, the larger the topological region.

The term “topological region” generally refers to a two-dimensional parameter plane wherein topological superconductivity occurs e.g., a phase space. A goal of the invention is to induce topological superconductivity within a device. Hence, numerous physical and material parameters, described throughout, can be fine-tuned to induce, optimize and increase the likelihood of topological superconductivity occurring within a device. Thus, a plurality of non-limiting materials, device layouts/geometries and architectures are exemplified herein as demonstrations of the invention.

As used herein “S” or “SC” can refer to the superconductor or superconductor/superconducting regions interchangeably. As will be described herein, in some embodiments a material can comprise physical and/or chemical properties which are inherently superconducting and in others superconductivity can be induced within a material e.g., by means of a gate-field or doping.

As used herein, the “normal” (N) region in an SNS and/or SNSNS junction, is considered any type of region that is not superconducting. Otherwise, as used herein, the term “normal” may be referred to interchangeably with the terms “trivial” or “insulating” inasmuch as the region does not display superconducting properties.

The term “phase winding” refers to a scenario wherein a phase of 2π creates a vortex which carries one unit of flux quantum. In general phase winding is a time-reversal symmetry breaking mechanism which assists in circulating current around the system. Phase winding can also occur at integers, or multiples of 2π i.e., 2πn where n is an integer greater than (but not including) zero. In some embodiments, utilizing phase winding together with unequal Fermi velocities can replace the need for an external Zeeman field.

In some embodiments, in the presence of spin-orbit coupling, the Fermi velocities are, in general, not equal, which forms a basis by which the present topological superconducting device operates. Herein “spin-orbit coupling” (SOC) generally refers to a relativistic interaction of a particle's spin with its motion inside a potential.

In some embodiments, the terms ‘leads’, ‘electrodes’, ‘pads’, ‘regions’, ‘terminals’ and ‘substrates’ are used interchangeably.

In some embodiments superconductivity in a material is induced by a gate potential, material doping or a combination thereof. In some embodiments a gate potential is applied directly (e.g., via leads) to the material and in other embodiments the gate potential is applied indirectly i.e., coupled to any number of other materials or layers such as oxides or other dielectric media. A dielectric medium refers to a medium which is an electrical insulator that can be polarized by an applied electric field.

As used herein “doping” or “chemical doping” refers to the introduction of an impurity (or impurities) with the purpose of modulating the materials' electrical, optical and/or structural properties.

In one embodiment more than one gate terminal interacts with any one of the SC regions. For example, an SC region can comprise an upper and/or a lower gate configuration such that the chemical potential is modulated in the SC region. In this embodiment, the gate potential defines the SC region which can define any shape and/or structure, as described below. Furthermore, the gate profile can be selected such that it optimizes the properties of the device. In some embodiments the gate biasing can be positive and in others it can be negative, and/or can vary from region to region of the device.

### Topological Superconducting Devices of the Invention

In some embodiments an SNSNS junction is comprised of one single material. In other embodiments, the S regions are comprised of different S materials. In one embodiment, gate-controlled superconductivity and unequal Fermi velocities in a single material (e.g., transition metal dichalcogenides) would not need quantum proximity coupling to an external superconductor and/or semiconductor. In some embodiments an SNSNS junction comprises more than one material.

In some embodiments, the geometric structure of the SNSNS junction, as embodied in a device, is primarily a planar junction but is not limited to this. The working principle of the invention is not limited to one particular device configuration, structure and orientation, as will be further detailed below. Furthermore, as will become clear, a plurality of the topological devices disclosed herein can be coupled together forming arrays of devices operating collectively. A 2D array of topological devices comprises a plurality of topological devices. In some embodiments the array comprises at least two topological devices. In some embodiments the array comprises between 2 and 10 topological devices. In some embodiments the array comprises between 2 and 100 topological devices. In some embodiments the array comprises between 100 and 1000 topological devices. In some embodiments the array comprises between 1000 and 5000 topological devices. In some embodiments the array comprises between 5000 and 10,000 topological devices. In some embodiments the array comprises between 10,000 to 1,000,000 topological devices. In some embodiments the array comprises between 1,000,000 and 1,000,000,000 topological devices. In some embodiments the array comprises between 1,000,000,000 and 1,000,000,000,000 topological devices.

Topological devices can be connected in arrays in any non-limiting manner, as known in the art. In some embodiments this is referred to as “topological superconducting array device”, “array device” or simply an “array”. The array device comprises a plurality of topological devices. In some embodiments, connecting topological devices is facilitated by any of the following non-limiting examples of materials, connection means and classes of materials: electrical connections, optical connections, connection by semiconductors, magnetic materials, alloys, magnetic semiconductors, magnetic insulators, superconductors, quantum materials and topological insulators. In some embodiments magnetic semiconductors are selected from: diluted magnetic semiconductors (DMS), yttrium iron garnet (YIG), bismuth iron garnet (BIG), magnetic oxides, half-metallic ferromagnets and magnetic topological insulators. Non-limiting examples of magnetic insulators includes ferrites, ceramic-based materials, rare-earth compounds, antiferromagnets, spin glasses and multiferroics. In some embodiments, the connection of topological devices is facilitated by any of the following: EuS, EuO, GdS:Eu, CoFe₂O₄, Cr₂Ge₂Te, including any compounds related to these families of materials. Further non-limiting examples of materials used for connecting topological devices of the present application include: rare earth metal chalcogenides, spinel ferrites, ceramic-based materials and TMDs.

Non-limiting examples of DMS materials are those doped with Mn, Fe or Co, for example (Ga,Mn)As, (In,Mn)As and (Zn,Mn)Te. Non-limiting examples of magnetic oxides include Fe₃O₄, CoFe₂O₄ and NiO. Non-limiting examples of magnetic topological insulators include Cr-doped (Bi,Sb)₂Te₃ and (Bi,Sb)₂Se₃.

Such devices and arrays can form components in devices such as the following non-limiting examples: electronic devices, integrated circuits, processors, quantum processors, quantum computers, quantum cryptography systems, quantum sensors and quantum communication systems. As used herein a “quantum computer” is a type of computer that uses qubits. A “qubit” being a unit of quantum information.

Reference will now be made to various figures which depict specific embodiments of the present invention. Those skilled in the art to which this invention pertains will readily appreciate that numerous changes, variations, and modifications can be made without departing from the scope of the presently disclosed subject matter, mutatis mutandis.

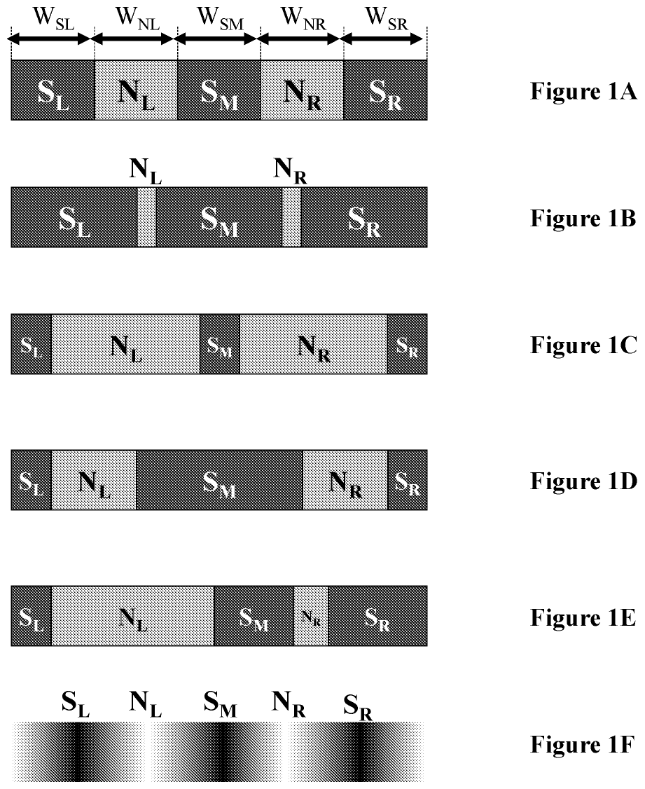

FIG. 1 illustrates a cross-section schema of different embodiments of an SNSNS junction and is labelled S_{L}N_{L}S_{M}N_{R}S_{R} wherein the subscript “L” corresponds to the ‘left’ side, the subscript “M” corresponds to the ‘middle’ and the subscript “R” corresponds to the ‘right’ side of the junction. In some embodiments, to describe the junction, the terms ‘section’, ‘region’ and ‘side’ are used interchangeably. In some embodiments the SNSNS junction is a planar device with parallel S and N regions or strips. Furthermore, the width of each S and N region of the S_{L}N_{L}S_{M}N_{R}S_{R} junction is denoted as “W” for convenience (see FIG. 1A). For example, W_{SL} refers to the width of the left S region. In some embodiments all S and N regions are the same width, i.e., W_{S}=W_{N}, as shown in FIG. 1A. FIG. 1A is labelled with this convention (S_{L}, W_{SL}, N_{L}, W_{NL}, etc.) and the S and N region labelling analogously applies to FIGS. 1B-1F as well. In some embodiments the width of each region in an SNSNS junction can be described by any one of the following scenarios:
W_{S}≠W_{N} (as shown in FIGS. 1B-1E)
W_{S}>W_{N} (as shown in FIG. 1B); or
W_{S}<W_{N} (as shown in FIG. 1C); or
W_{SL}=W_{SR} and W_{SM}>W_{SL/SR/NL/NR} (as shown in FIG. 1D); or
W_{SL}≠W_{NL}≠W_{SM}≠W_{NR}≠W_{SR} (one example is shown in FIG. 1E).

In some embodiments the boundary and/or interface between S and N regions are well defined, which is depicted as separating S and N regions by a line (for example see FIGS. 1A-1E). In other embodiments the S and N regions, and the boundary/interfaces thereof, are not clearly defined (for example see FIG. 1F). In one sense FIGS. 1A-1E illustrate idealized configurations of SNSNS junctions, which does not detract from the essence of the invention, even though in ‘real world’ scenarios interfaces between materials (or one or more materials with regions of differing electronic states) may be less idealized. In some embodiments, the boundary and/or interface between S and N regions are continuous. In other embodiments the boundary and/or interface between S and N regions are discontinuous. In some embodiments S and N regions blur into one another and/or are continuous (see FIG. 1F). The term “boundary” generally refers to a line that defines where one region begins and the other ends. The term “interface” generally refers to a region where two different systems, materials and/or items interact with one another.

In some embodiments the three superconducting regions are adjacent to one another. As used herein, “adjacent” can refer to regions that are touching, next to, near or in proximity of each other, even if they may be fully or partially separated.

In some embodiments, any of the layers and/or regions in a device form a structure as a component in a device as any one of the following: a monolayer, surface, thin film, layer and/or 3D shape/structure. In some embodiments, the structures of the device are fabricated by any one of the following: photolithography, electron-beam-lithography processes, physical vapor deposition, chemical vapor deposition, epitaxy, focused ion-beam, self-assembly, nanoimprinting, dry/wet etching, electrically induced nanopatterning, dry/wet deposition and/or a combination thereof.

In one embodiment the thickness of the SC and N layers in the device range from between 1 nanometer and 1000 nanometers. In one embodiment the thickness of the SC and N layers in the device range from between 1 nanometer and 200 nanometers. In one embodiment the thickness of the SC and N layers in the device range from between 1 nanometer and 500 nanometers. In one embodiment the thickness of the SC and N layers in the device range from between 500 nanometer and 1000 nanometers. In another embodiment the thickness of the SC and N layers in the device range from between 1 micron and 20 microns. In another embodiment the thickness of the SC and N layers in the device range from between 1 micron and 50 microns. In another embodiment the thickness of the SC and N layers in the device range from between 50 micron and 100 microns.

In another embodiment, the different S and/or N structures within the SNSNS device are of the same thickness and in other embodiments the thickness of different S and/or N structures are not the same. In another embodiment, the different SC and/or N structures within the SNSNS device are of the same and in other embodiments the shape of the different SC and/or N structures are not the same.

In some embodiments, the gate potential tunes a materials' electrical properties from insulating to superconducting e.g., in Al substrates. In some embodiments any material that has spin-orbit coupling can be used at the functional material. In some embodiments, quantum proximity of the SC region with the substrate is required. In some embodiments, phase-tuning of a superconducting state is realized by gates within the SNSNS device. In some embodiments, a single material can be used wherein a plurality of gates are used to induce superconductivity in specific regions, such as to form an SNSNS device within one material. In such an embodiment, there is no need for coupling to a 2D electron gas (2DEG) substrate.

In some embodiments a combination of intrinsic gate-controlled superconductivity and unequal Fermi velocities in layers of TMDs exhibits topological superconductivity in a single material system, without the need for quantum proximity coupling to an external superconductor.

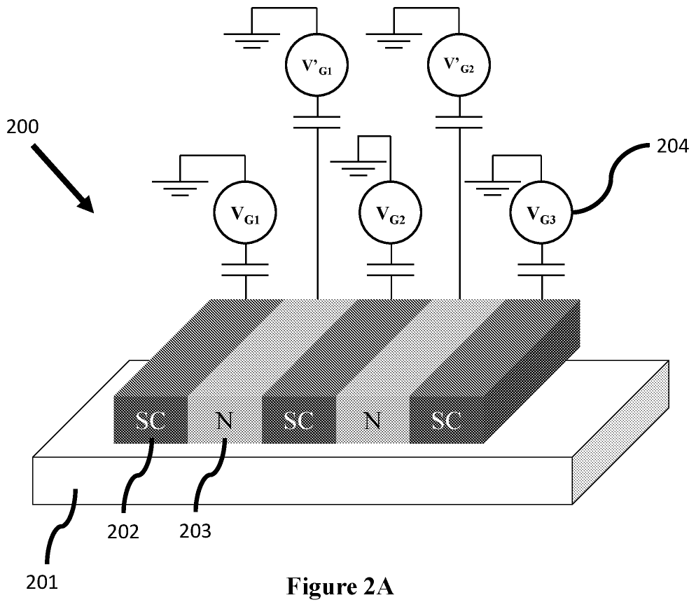

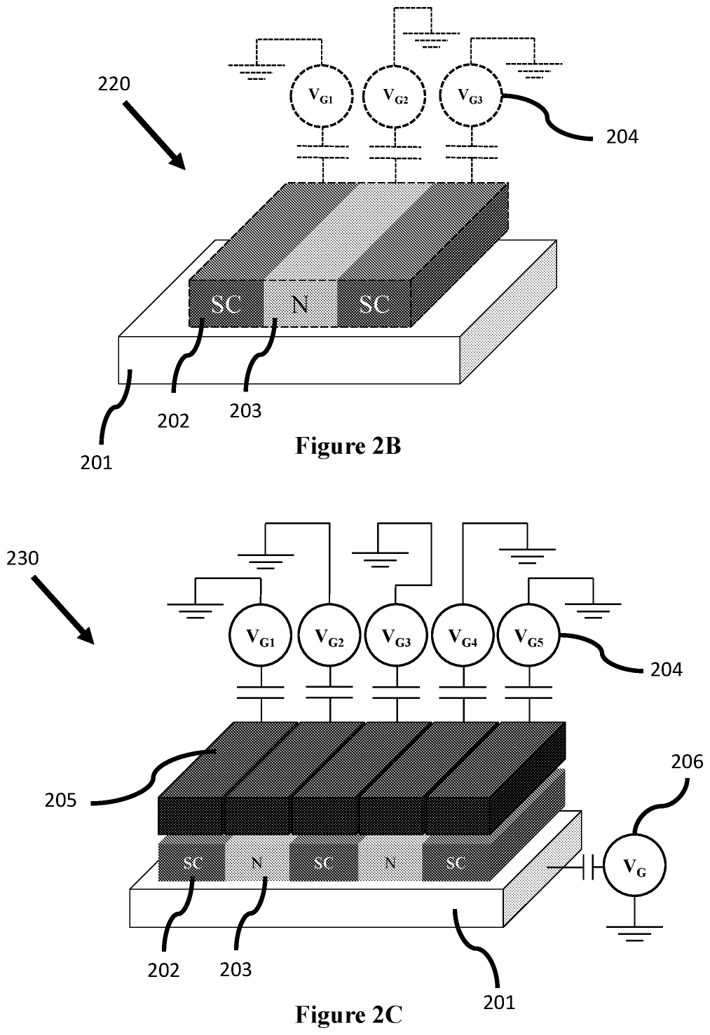

As illustrated in the schematic of FIG. 2A, the device 200 comprises SC regions 202 separated by N regions 203, disposed on a substrate 201 and at least one gate 204, three of which are depicted on the SC regions labelled V_{G1}, V_{G2} and V_{G3}, and two are depicted on the N regions labelled as V′_{G1}, V′_{G2}, shown as top-gates. For the purpose of clarity not all coupling layers and structures are shown in FIG. 2A. The at least one gate 204, or plurality of gates, are shown as being connected to the SC and/or regions 202 via capacitors. In some embodiments, any number of gates can be used. In some embodiments, any number of additional layers (not shown), e.g., dielectric materials, are coupled to a plurality of electrodes to facilitate gating to any of the SC regions 202 and/or N regions 203. In some embodiments the dielectric material is selected from: silicon, silicon oxide, silicon nitride, aluminum oxide, hafnium oxide, zirconium oxide, titanium dioxide, superconducting layer, semiconductor, topological insulating layer and polymers or any combinations thereof. In some embodiments, additional layers comprise at least one metal. In some embodiments, additional layers comprise graphene. These additional layers may be applied to any of the devices disclosed herein. In some embodiments additional layers comprise any of the following selected from: transition metal oxides, topological insulators, heavy fermion materials, semiconductors and organic molecules or any combinations thereof. The device 200 comprises at least three superconducting (SC) regions 202 made of a superconducting material and being in a superconducting state. In some embodiments, the SC and/or N regions can be adjacent regions, parallel strips or pads. A non-superconducting region (N) 203 separates each SC region 202 forming two connected SNS junctions, namely an SNSNS junction or device, disposed upon a substrate 201. In one embodiment the SC regions 202 and N regions 203, i.e., SNSNS junction, are disposed on a non-superconducting substrate 201. According to some examples, the substrate 201 may comprise any one of, but not limited to, a non-superconducting metal, a semiconductor, a dielectric medium, an oxide and/or a combination thereof. In some embodiments the terms “topological device”, “device” and “junction” are used interchangeably. The gates 204 are shown schematically as top-gates indirectly connected to the SC regions 202 and N regions 203, although, as will become apparent below, the implementation of a gate-field is not limited to one particular set up. The gate-potential of any one of the gates used can be the same or different. In some embodiments, each gate 204 can provide a fixed (DC) or oscillating (AC) voltage. Said voltage can be applied directly to the corresponding region or indirectly via subsequent layers and/or electrodes e.g., a plurality of electrodes, appropriately placed and coupled. In some embodiments, the applied voltage profile is non-linear, pulsed, periodic and/or non-periodic. In some embodiments any one of the gates 204 can control the gate potential in one or more of the SC regions 202 and/or N regions 203.

As illustrated in FIG. 2B, additional SNS junctions 220 comprising SC regions 202 separated by N regions 203, disposed on a substrate 201, can be added to existing SNS or SNSNS junctions, in parallel. For the purpose of clarity not all coupling layers and structures are shown in FIG. 2B. Accordingly, each SC and/or N region can comprise its own corresponding gate 204. In some embodiments, each gate 204, or plurality of gates, is connected to the SC regions 202 and/or N regions 203 via capacitors. In some embodiments, any number of layers of dielectric materials are coupled to a plurality of electrodes to facilitate gating to any of the SC regions 202 and/or N regions 203. Furthermore, each SNSNS device can further comprise at least one additional SC region 202 and/or at least one additional N region 203. Therefore a plurality of the topological devices disclosed herein can be coupled together forming arrays of devices operating collectively. In one embodiment a plurality of topological devices are coupled together forming an array of topological devices. In principle the connecting of a plurality of devices is extended to any of the devices disclosed herein.

As illustrated in FIG. 2C a device architecture 230 comprises an SNSNS junction with SC regions 202 separated by N regions 203 disposed on top of a substrate 201. For the purpose of clarity not all coupling layers and structures are shown in FIG. 2C. The SC regions 202 and N regions 203 are defined by a plurality of top-gate electrodes 204, disposed in a top layer 205, shown as strips, and additionally wherein the substrate 201 is back-gated 206. The top gates 204 and bottom gates 206 tune the gate potential across the central layer which comprises the SNSNS junction, modulating the electronic properties in the SC regions 202 and N regions 203. The electronic properties of the SNSNS layer can thus be controlled by gates. A plurality of such a device can be connected to form an array of devices operating collectively.

In some embodiments of the devices presented herein, the height, width, thickness and/or shape, of any of the SC and/or N and/or insulating regions can vary across the device. Furthermore, the devices presented schematically in the figures can incorporate additional layers in-between, next to, on top of and underneath any of the depicted layers to facilitate electronic coupling, or insulating of various parts of the device, as required by the device architecture, to achieve the stated aims of the present invention.

In some embodiments, the functional material used in the device may be made from any suitable superconducting material. In some embodiments, the superconducting material comprises: type I superconductors, type II superconductors, organic superconductors, iron-based superconductors and rare-earth metal based superconductors or any combination thereof. Non-limiting examples include Al, Nb, Pb, NbSe₂, HgTe, InAs, InSb and transition metal dichalcogenides (TMD). All of the substrates and/or electrodes, may be made from the same material, or two or more may be made from different materials. The functional and/or non-functional elements of a device can include TMDs, of which non-limiting examples include: MX₂ (M=Mo, W; X=S, Se, Te) MoS₂, MoSe₂, MoTe₂, WS₂, WSe₂, TaS₂, or WTe₂ or combination thereof. Indeed, any material that supports Fermi velocity imbalance can be used as the functional material for carrying out the invention. TMDs support Fermi velocity imbalance, which provides a platform to fulfil one of the conditions of the present invention. In some embodiments, any material can be used which exhibits strong spin-orbit coupling and exhibits Fermi velocity imbalance in two separate branches of the device.

According to some examples the material of the substrate is different from that of the SC or N materials.

One means of carrying out the present invention is in utilizing gate-controlled tuning of superconducting materials. In some embodiments gate-controlled tuning of a material, namely, utilizing a gate to define a “quantum wire”. Herein “quantum wire” refers to a structure embedded inside, on top of, or below a substrate, material, layer and/or film whose properties have been modulated by a gate field to exhibit quantum properties, such as superconductivity.

In some embodiments a plurality of quantum wires can be placed in parallel, along with a corresponding gate-electrode, to achieve the SNSNS structure. Gate-defined superconducting region, such as a quantum wire, can be extrapolated to any desired shape and device structure, according to the requirements of a particular device optimized to achieve the required topological superconductivity, in two or three spatial dimensions. Indeed, in some embodiments, a plurality of top, bottom and/or side-gates can be used independently or in any combination, to achieve the desired gate-field and/or gate-profile, and couple said gate to an SC and/or N region.

In one embodiment, the S material of the SNSNS device is incorporated into a layered structure. In one embodiment, SNSNS junctions further comprise at least one or more of any one of the following additional materials: S material, N material, doped material, semiconducting material, dielectric material, oxide, insulating material, metal, 2D electron gas material, TMD, electron conductors and hole conductors or any combination/s thereof. As used herein a “2D electron gas material” refers to a material which comprises an electron gas that is free to move in two dimensions but is tightly confined in the third dimension. In some embodiments, any of the materials described herein can be doped. In some embodiments the SC material can be selected from any material platform which supports large spin-orbit semiconducting quantum wells such as, but not limited to, HgTe, InAs and InSb.

### Topological Superconducting Devices With Periodic Modulations

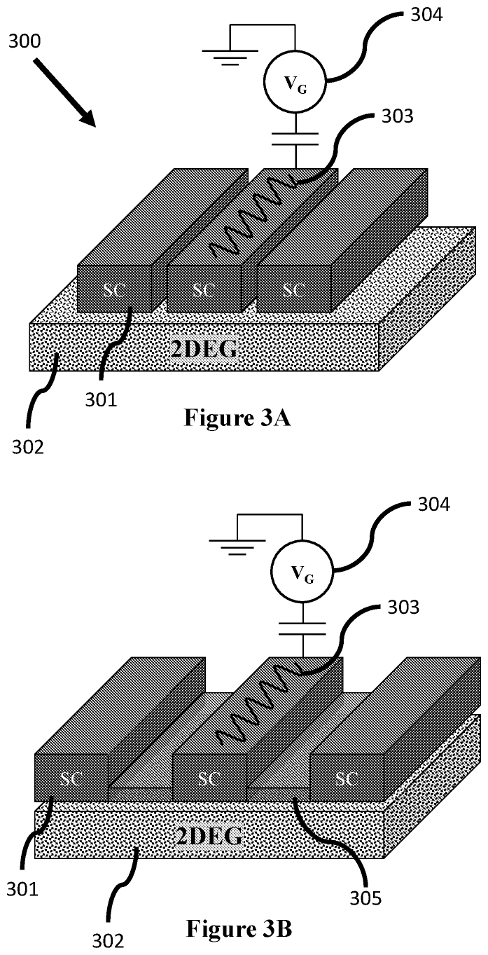

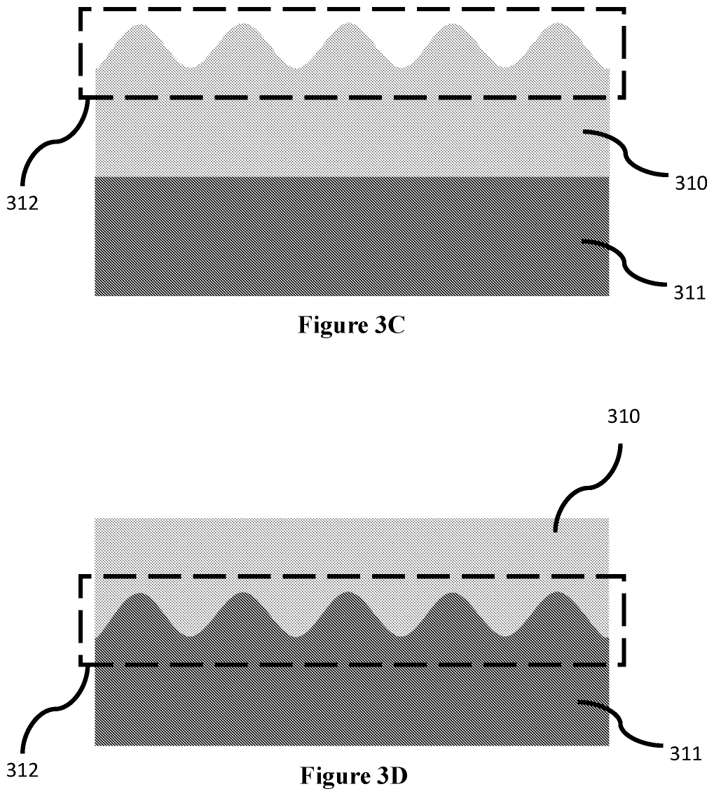

FIG. 3 illustrates ways to induce unequal Fermi velocities, as shown in certain embodiments, combining Rashba SOC with a periodic modulation 303 along the junction i.e., longitudinally, which can induce topological superconductivity. For the purpose of clarity not all coupling layers and structures are shown in FIG. 3. As shown in FIG. 3, a device 300 with three SC regions 301 which are laterally separated, are disposed on top of a spin-orbit coupled 2D electron gas 302 (i.e., a substrate) wherein the middle superconducting region has a periodic modulation 303, represented by a sine wave, thereby inducing a topological phase. In some embodiments the SC region 301 is directly in contact with, or in quantum proximity to, the 2DEG 302 and in other embodiments there is at least one layer separating the SC region 301 and the 2DEG 302. In some embodiments, a periodic modulation 303 induces a modulation to the chemical potential of the middle superconductor. In other embodiments, the periodic modulation 303 induces a modulation in the chemical potential of a superconductor, which isn't the middle one.

In some embodiments, the periodic modulation 303 along the middle SC region is a physical periodic structure along the SC region 301. Any periodic structural modulation can be utilized such as a sinusoidal wave, square-wave, saw-tooth, zigzag, etc. In some embodiments the periodic modulation is on the surface, under-side or inside, or a combination thereof, of any of the following: the SC regions 301, the N regions, an intermediate material 305, the substrate, one of the gate electrodes or any other coupling material or any combination thereof. As used herein “coupling material” refers to any material disposed on top of, underneath, or next to another material and/or layer. In some embodiments the coupling material may be any group selected from: a non-superconducting metal, a 2DEG material, a semiconductor, a dielectric medium, silicon, an oxide or combination thereof. In some embodiments, the periodic modulation 303 is achieved by scratching the surface. In some embodiments the periodic modulation 303 is partly uniform.

FIG. 3C illustrates a schematic representation of a top layer 310 and a bottom layer 311 in a device. These two layers can represent any of the layered materials in the planar device of the present invention e.g., the SNSNS junction disposed on a substrate. In some embodiments the top layer 310 has a periodic modulation 312 on the top surface in the form of a sinusoid. The region comprising the periodic modulation 312 is indicated by a dotted rectangle. FIG. 3D illustrates a periodic modulation 312 at the interface or boundary between the top layer 310 and the bottom layer 311.

In some embodiments the height of the periodic modulation 312 is in the range 1 to 10 nm. In some embodiments the height of the periodic modulation 312 is in the range 1 to 50 nm. In some embodiments the height of the periodic modulation 312 is in the range 1 to 100 nm. In some embodiments the height of the periodic modulation 312 is in the range 50 to 100 nm. In some embodiments the height of the periodic modulation 312 is in the range 100 to 500 nm. In some embodiments the height of the periodic modulation 312 is in the range 500 to 1000 nm. In some embodiments the height of the periodic modulation 312 is in the range 1 to 10 μm. In some embodiments the height of the periodic modulation 312 is in the range 5 to 10 μm. In some embodiments the height of the periodic modulation 312 is greater than 10 μm. As used herein “height” refers to the amplitude of the periodic modulation 312.

In some embodiments, as shown in FIG. 3A and FIG. 3B, a top gate 304 can be connected to any one of the SC regions 301 and apply a constant or oscillating voltage, appropriately placed and coupled. Said voltage can be applied directly to the corresponding region or indirectly via additional layers and/or electrodes e.g., a plurality of electrodes and dielectric materials. In some embodiments, the applied voltage profile is non-linear, pulsed, periodic and/or non-periodic. In some embodiments, the 2DEG is a substrate 302 upon which the superconducting regions 301 are disposed thereon. In another embodiment the superconducting regions 301 are separated by an intermediate material 305 and/or separated from the substrate, as shown in FIG. 3B. In some embodiments the separating intermediate material 305 can be any one of the following: a superconducting material in a non-superconducting state, an insulator, a semiconductor, a 2DEG material and/or an oxide. In further embodiments, the superconducting regions 301 are quantum wires defined by gate-electrodes. In some embodiments, the devices of FIG. 3A and FIG. 3B can incorporate more than one gate.

### Phase Winding and Unequal Fermi Velocities

In one-dimensional superconducting systems where time reversal symmetry is broken and translational invariance holds, a transition between trivial and topological phases occurs when there is a single gap closing at zero longitudinal momentum (kₓ=0). For such a single gap closing to occur, spin symmetry must be broken. In many models, the relevant parameter space is two dimensional, with one parameter—the Zeeman energy—breaking the symmetry of the two spin branches. The second parameter is the phase difference for planar Josephson junctions. The application of the Zeeman field separates between the gap closing curves of the two spin branches in the parameter space, thereby separating trivial and topological regions.

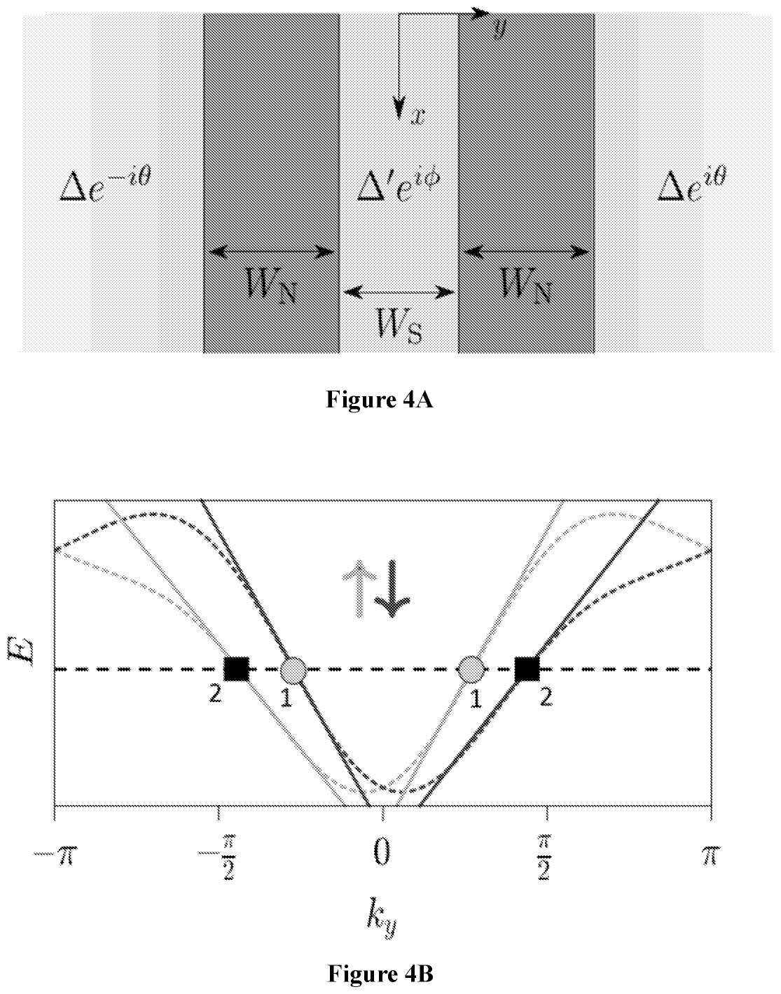

FIG. 4 shows a phase-biased SNSNS junction (superconducting regions are light grey, normal regions are dark grey). An SNS junction between two superconductors have order parameters Δe^{±iθ}. If the superconducting gap Δ is much smaller than the Fermi energy E_{F}, then at θ=π/2, where the phase difference across the junction is π, a double gap closing occurs at the junction, with four states at zero energy. A third superconductor is introduced in the middle of the junction with an order parameter of Δ′e^{iϕ}, see FIG. 4A, wherein regions between single gap-closing curves in θ−ϕ space correspond to a topological phase.

The two outer superconductors are semi-infinite in the transverse direction, y, and their superconducting order parameter, Δ, is, in general, different from the middle superconductor, Δ′. At kₓ=0 this reduces to a one-dimensional problem, whose zero energy crossings correspond to topological phase transitions. In FIG. 4B a transverse spectrum of the junction (dashed lines), in a model including next-nearest neighbor hopping. At the Fermi energy (central dashed black line in FIG. 4B), there are four Fermi points (represented as two circles, labelled ‘1’, and two squares, labelled ‘2’). The Fermi velocities at the “outer” branch (two black squares at k_{y}=±π/2) and in the “inner” branch (two grey circles closer to k_{y}=0) are not identical. Solid lines correspond to the linearized spectra.

Materials can be characterized in terms of their band structure and in many cases next-nearest neighbor interactions can be utilized to obtain an empirically observed band structure. Such a band structure can then be used to determine whether a material is suitable for implementation as a component in a topological superconducting device. Materials can thus be selected which exhibit the desired topological superconducting state e.g., one with the largest topological region. For example, 2DEGs of different thicknesses can exhibit a different number of bands and sub-bands which can be selected for to optimize topological superconducting characteristics.

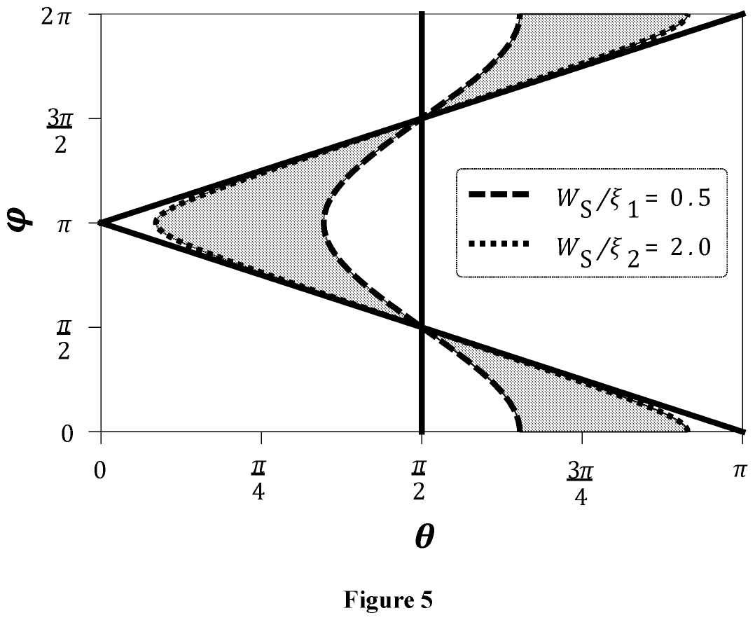

When two spin branches have different velocities, the Zeeman field may be replaced by a second phase difference. In the presence of spin-orbit coupling the Fermi velocities ν₁, ν₂ are, in general, not equal. The position of the gap-closing transition within the θ−ϕ plane is determined by the dimensionless ratio Wₛ/ξⱼ, where ξⱼ=νⱼ/Δ′ is the coherence length of the middle superconductor for branch j and where W_{S} is the width of the middle superconductor. When the middle superconductor is absent (W_{S}=0), the transition occurs for both spins at θ=π/2, giving a phase difference of π. When the middle superconductor is very wide, the system may be seen as two disconnected junctions, and a gap closing takes place when the phase difference across one junction is π. In between, the position of the gap closing creates a curve in the θ−ϕ plane. In an SNSNS junction, when the velocities in the middle superconductor are unequal, the gap-closing curves for the two spin branches are different. The area between these curves defines the topological region, as illustrated in FIG. 5. A large topological region (represented by the shaded grey area in between the two non-linear curves) results from very different Fermi velocities for the two branches. The extreme limits are ξⱼ=0, which corresponds to θ=π/2, and ξⱼ→∞, corresponding to ϕ=π±θ.

FIG. 5 shows a phase diagram for the SNSNS geometry of FIG. 4. The two values of ξⱼ=vⱼ/Δ′ originate from the unequal transverse Fermi velocities. The wide-dotted-line curve and the short-dotted curve correspond to zero-energy crossings at kₓ=0 for W_{S}/ξ₁=0.5 and W_{S}/ξ₂=2, respectively. Since each of these crossings is non-degenerate, it corresponds to a topological phase transition, and therefore the area between the two curves (shaded area) harbors a topological superconducting state. The solid black lines define the region where a vortex is present.

There are several material platforms where the band structure has such an imbalance wherein the Fermi velocities for the two spin branches are unequal. In some embodiments, the present invention supports any material that exhibits unequal Fermi velocities in an SNSNS configuration, such as TMDs. In some embodiments, a single-material system can be utilized by intrinsic gate-controlled superconductivity and unequal Fermi velocities in layers of TMDs without the need to proximity couple with an external superconductor.

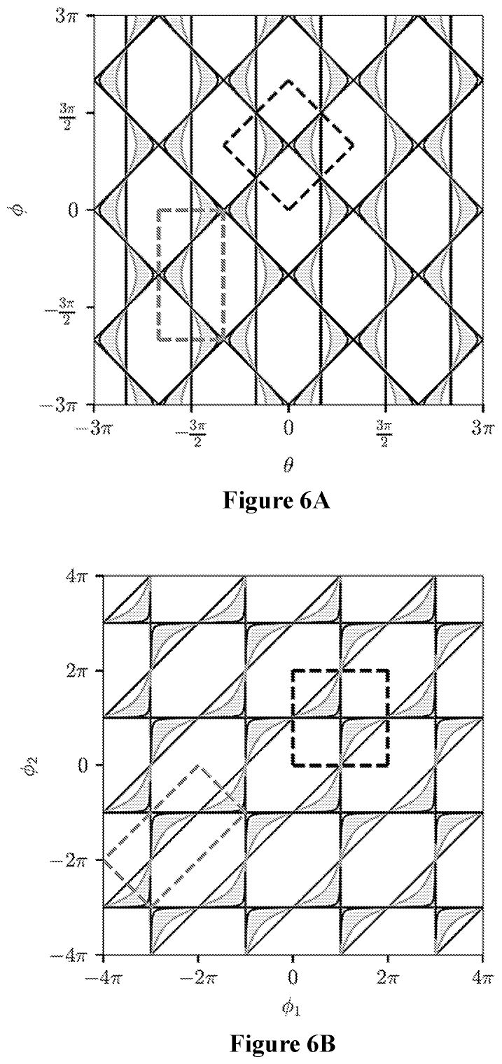

FIG. 6 shows the inherent periodicity of the phases, distinguishing the topological effects from the trivial ones, as mapped out in the phase diagram. FIGS. 6A and 6B show that the periodic pattern appearing is unique to the phase-induced setup. The dashed black squares denote unit cells, and the dashed gray rectangles show the section of the phase diagram shown in FIG. 5.

It will be appreciated that the examples described above, as embodied in various figures, are by way of example, and a device may be provided according to the presently disclosed subject matter or any other configuration that achieves the stated goals of the invention. Furthermore, the presently disclosed examples and embodiments serve to provide a platform wherein the phase difference of the materials in the devices can be controlled, selected and/or tuned in order to provide the required parameters such as phase winding and an unequal Fermi velocity of the materials in the device.

As such, those skilled in the art to which this invention pertains will readily appreciate that numerous changes, variations, and modifications can be made without departing from the scope of the presently disclosed subject matter, mutatis mutandis.

1. A topological superconducting device comprising:
three adjacent superconducting regions, comprising at least one material, disposed on a substrate, giving rise to two spin branches;
wherein the said three adjacent superconducting regions exhibit phase winding; and
wherein one spin branch has a Fermi velocity that is not the same as the Fermi velocity of the second spin branch.

2. The topological superconducting device of claim 1 further comprising at least one gate.

3. The topological superconducting device of claim 1 further comprising two non-superconducting regions disposed between said three adjacent superconducting regions, arranged as two SNS junctions with one overlapping superconducting region forming an SNSNS junction.

4. The topological superconducting device of claim 1 wherein the said three adjacent superconducting regions are arranged in parallel to one another and/or in a planar configuration.

5. The topological superconducting device of claim 1 wherein said substrate is selected from a group comprising: a non-superconducting metal, a 2D electron gas material, a semiconductor, a dielectric medium, silicon, an oxide or combination thereof.

6. The topological superconducting device of claim 3 wherein said two SNS junctions comprise at least one material wherein said at least one gate is configured to modulate superconductivity in said at least one material.

7. The topological superconducting device of claim 2 wherein said at least one gate is configured to modulate phase differences between said three adjacent superconducting regions.

8. The topological superconducting device of claim 2 wherein said three adjacent superconducting regions are gate-defined wires.

9. The topological superconducting device of claim 1 wherein the middle superconducting region of said three adjacent superconducting regions is wider than the width of the outer superconducting regions.

10. The topological superconducting device of claim 1 wherein said at least one material is selected from a group comprising: a transition metal dichalcogenide (TMD), Al, Nb, Pb, NbSe₂, HgTe, InAs and InSb; and wherein said TMD is selected from a group comprising: TaS₂, MoS₂, MoSe₂, MoTe₂, WS₂, WSe₂, WTe₂ or combination thereof.

11. (canceled)

12. The topological superconducting device of claim 1 wherein said at least one material is doped.

13. The topological superconducting device of claim 1 wherein said phase winding occur at multiples of 2π.

14. The topological superconducting device of claim 3 further comprising a periodic modulation on top of, underneath and/or inside at least one of said three adjacent superconducting regions.

15. The topological superconducting device of claim 1 further comprising at least one additional superconducting region parallel to said three adjacent superconducting regions.

16. The topological superconducting device of claim 15 further comprising at least one additional non-superconducting region between said at least one additional superconducting region parallel to said three adjacent superconducting regions.

17. The topological superconducting device of claim 1 further comprising additional layers in-between, next to, on top of and/or underneath said least three superconducting regions.

18. The topological superconducting device of claim 2 wherein the said at least one gate comprises a top-gate, back-gate, side-gate or combination thereof.

19. A quantum computer comprising the device of claim 1.

20. A topological superconducting array device comprising a plurality of the device according to claim 1.

21. A quantum computer comprising the array device of claim 20.
